(19) United States
(12) Patent Application Publication
(10) Pub. No.: US 2025/0276420 A1
(43) Pub. Date: Sep. 4, 2025

(54) ACOUSTIC SENSOR, METHOD OF MANUFACTURING THE SAME, AND CHEMICAL MECHANICAL POLISHING APPARATUS

(71) Applicant: SAMSUNG ELECTRONICS CO., LTD., Suwon-si (KR)

(72) Inventors: Se Yun PARK, Suwon-si (KR); Dong Hoon KWON, Suwon-si (KR)

(73) Assignee: SAMSUNG ELECTRONICS CO., LTD., Suwon-si (KR)

(21) Appl. No.: 18/906,677

(22) Filed: Oct. 4, 2024

(30) Foreign Application Priority Data
Mar. 4, 2024 (KR) 10-2024-0030855

(51) Int. Cl. B24B 49/00; B24B 37/013; B24B 37/04; H10N 30/50; H10N 30/853; H10N 30/87

(52) U.S. Cl. CPC B24B 49/003; H10N 30/50; H10N 30/871; H10N 30/875; B24B 37/013; B24B 37/042; H10N 30/8536; H10N 30/8554

(57) ABSTRACT

An acoustic sensor includes a first electrode, a second electrode spaced apart from the first electrode in a first direction, and a first piezoelectric structure between the first electrode and the second electrode, where the first piezoelectric structure includes first nanowires extending in the first direction and having a first height and second nanowires extending in the first direction and having a second height that is less than the first height.

### CROSS-REFERENCE TO RELATED APPLICATION

This application is based on and claims priority to Korean Patent Application No. 10-2024-0030855, filed on Mar. 4, 2024, in the Korean Intellectual Property Office, the disclosure of which is incorporated by reference herein in its entirety.

### BACKGROUND

Example embodiments of the disclosure relate to an acoustic sensor, a method of manufacturing the same, and a chemical mechanical polishing (CMP) apparatus.

A chemical mechanical polishing (CMP) apparatus may be used in a polishing process to flatten the surface of a semiconductor wafer. As a method to determine the endpoint of the polishing process in the CMP apparatus, an endpoint detector (EPD) that emits light on the surface of the semiconductor wafer and detects a reflected light signal may be utilized. However, this type of EPD may induce light scattering due to a slurry solution used during the polishing process, leading to noise in the light signal.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate processing apparatus with improved reliability.

Additional aspects will be set forth in part in the description which follows and, in part, will be apparent from the description, or may be learned by practice of the presented embodiments.

According to an aspect of an example embodiment, an acoustic sensor may include a first electrode, a second electrode spaced apart from the first electrode in a first direction, and a first piezoelectric structure between the first electrode and the second electrode, where the first piezoelectric structure includes first nanowires extending in the first direction and having a first height and second nanowires extending in the first direction and having a second height that is less than the first height.

According to an aspect of an example embodiment, a chemical mechanical polishing apparatus may include a polishing platen, a polishing pad on the polishing platen, a polishing head on the polishing pad and including a wafer receptacle configured to accommodate a wafer, and an acoustic sensor in the polishing pad, where the acoustic sensor includes a first electrode, a second electrode spaced apart from the first electrode in a first direction, and a first piezoelectric structure between the first electrode and the second electrode, where the first piezoelectric structure includes first nanowires extending in the first direction and having a first height and second nanowires extending in the first direction and having a second height that is less than the first height.

According to an aspect of an example embodiment, a method of manufacturing an acoustic sensor may include providing a seed layer on a first electrode, forming first nanowires on the seed layer, the first nanowires extending in a first direction and having a first height, forming second nanowires on the seed layer, the second nanowires extending in the first direction and having a second height that is less than the first height, forming a connection film contacting top surfaces of the second nanowires, and providing a second electrode on the connection film.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a chemical mechanical polishing (CMP) apparatus according to one or more embodiments;

FIG. 2 is a top view illustrating a CMP apparatus according to one or more embodiments;

FIG. 3 is a cross-sectional view taken along line A-A′ of FIG. 1 according to one or more embodiments;

FIG. 4 is a perspective view illustrating an endpoint detector (EPD) according to one or more embodiments;

FIG. 5 is a perspective view illustrating an acoustic sensor according to one or more embodiments;

FIG. 6 is a top view illustrating an acoustic sensor according to one or more embodiments;

FIG. 7 is a diagram illustrating components depicted in FIG. 5 according to one or more embodiments;

FIG. 8 is cross-sectional view illustrating an example taken along line B-B′ of FIG. 6 according to one or more embodiments;

FIG. 9 is cross-sectional view illustrating an example taken along line B-B′ of FIG. 6 according to one or more embodiments;

FIGS. 10 through 14 are perspective views illustrating a method of manufacturing an acoustic sensor according to one or more embodiments;

FIG. 15 is a cross-sectional view illustrating portion P1 of FIG. 5 according to one or more embodiments;

FIG. 16 is a cross-sectional view illustrating portion P2 of FIG. 5 according to one or more embodiments;

FIG. 17 is a perspective view illustrating an acoustic sensor according to one or more embodiments;

FIG. 18 is a perspective view illustrating components depicted in FIG. 17 according to one or more embodiments;

FIG. 19 is a perspective view illustrating an acoustic sensor according to one or more embodiments; and

FIG. 20 is a perspective view illustrating an acoustic sensor according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

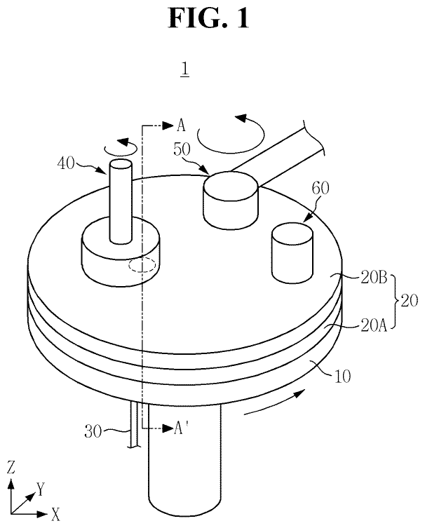

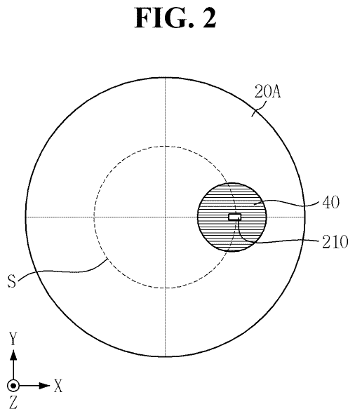

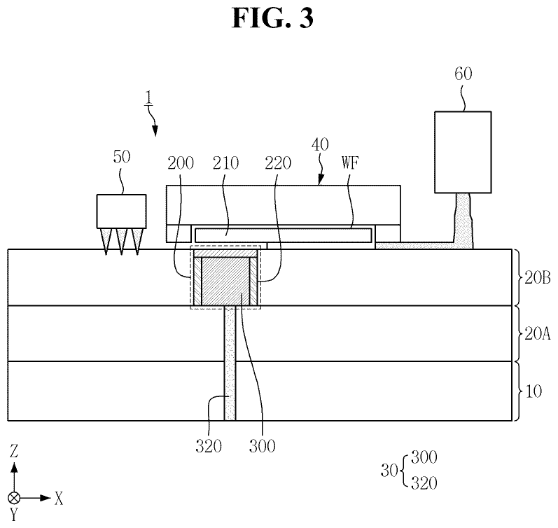

FIG. 1 is a perspective view illustrating a chemical mechanical polishing (CMP) apparatus according to one or more embodiments. FIG. 2 is a top view illustrating a CMP apparatus according to one or more embodiments. FIG. 3 is a cross-sectional view taken along line A-A′ of FIG. 1 according to one or more embodiments.

Referring to FIGS. 1 through 3, a CMP apparatus 1, which may be an apparatus for polishing a wafer WF, may include a polishing platen 10, a polishing pad 20, an endpoint detector (EPD) 30, a head portion 40, a conditioner 50, and a slurry supply 60.

The CMP apparatus 1 may perform mechanical polishing by placing the wafer WF that is mounted on the bottom surface of the head portion 40 to contact the polishing pad 20, and may perform chemical polishing through a chemical reaction caused by a slurry supplied from the slurry supply 60.

The polishing platen 10 may be a member that applies rotational energy to allow the polishing pad 20 to rotate in a predetermined direction. Specifically, the polishing pad 20 may be disposed (or attached) on the polishing platen 10 and may be rotated by driving the polishing platen 10. The polishing pad 20, which may uniformly flatten the surface of the wafer WF, may be a member that performs mechanical polishing. The polishing pad 20 may be located on the polishing platen 10 and may be rotated by driving the polishing platen 10.

The polishing pad 20 may include a lower polishing pad 20A, which is disposed on the polishing platen 10, and an upper polishing pad 20B, which is disposed on the lower polishing pad 20A. The upper polishing pad 20B may include a hole 200, which accommodates an acoustic sensor 300. FIG. 3 illustrates the hole 200 as being formed inside the upper polishing pad 20B, but alternatively, the hole 200 may be formed either entirely or partially in the upper polishing pad 20B, as well as in the lower polishing pad 20A.

In one or more embodiments, the upper polishing pad 20B may include a housing 220, which surrounds the sides of the acoustic sensor 300, and a window 210, which covers the top surface of the acoustic sensor 300. Additionally, in one or more embodiments, the polishing platen 10 and the lower polishing pad 20A may include a hole, which penetrates the polishing platen 10 and the lower polishing pad 20A in a vertical direction (e.g., a third direction Z) and accommodates a signal cable 320.

The EPD 30 may be a member for measuring the thickness of the polishing layer of the wafer WF. The EPD 30 may include the acoustic sensor 300 and the signal cable 320. The acoustic sensor 300 may be contained within the hole 200, which penetrates the upper polishing pad 20B. FIG. 2 illustrates that the hole 200 is formed within the upper polishing pad 20B, but the hole 200 may also be formed in the lower polishing pad 20A. In this case, the acoustic sensor 300 may be contained within the hole 200 formed in both the upper and lower polishing pads 20B and 20A.

In one or more embodiments, the signal cable 320 may be located within a hole that penetrates the polishing platen 10 and/or the lower polishing pad 20A in a direction perpendicular to the top surface of the polishing pad 20 (for example, in the Z direction).

An electronic signal generated from the acoustic sensor 300 may be transmitted to an external control device through the signal cable 320, which is connected between the acoustic sensor 300 and the external control device. The external control device may determine the endpoint of a polishing process based on the signal received from the acoustic sensor 300. The polishing layer of the wafer WF may refer to the layer of the wafer WF that contacts a polishing target, such as a semiconductor device, and that has a polishing surface that polishes the polishing target.

In one or more embodiments, the EPD 30 may determine the endpoint of the polishing process by detecting sound waves or vibrations generated from the polishing surface of the wafer WF during the polishing process. Thus, the EPD 30 may include the acoustic sensor 300.

Specifically, the acoustic sensor 300 may include a piezoelectric material that converts sound waves or vibrations into electrical signals. An electrical signal generated from the piezoelectric material may be transmitted to the external control device through the signal cable 320, and the external control device may determine the endpoint of the polishing process based on the electrical signal.

For example, different sound waves or vibrations may be generated from the polishing surface of the wafer WF depending on the thickness of a material to be polished or the type of film located on the polishing surface. For example, the intensity or wavelength of the sound waves or vibrations generated from the polishing surface may vary depending on the thickness or type of the film located on the polishing surface. Accordingly, the intensity or wavelength of the electrical signal generated from the piezoelectric material included in the acoustic sensor may also vary. The external control device may determine the endpoint of the polishing process based on information on the intensity or wavelength of the electrical signal.

The head portion 40 may be a rotatable member that may mount the wafer WF. Specifically, the head portion 40 may include a receptacle, which accommodates the wafer WF. While being accommodated in the head portion 40, the wafer WF may be supported by the receptacle. While being accommodated in the head portion 40, the wafer WF may contact the top surface of the upper polishing pad 20B on one side.

During the polishing process, the head portion 40 may rotate. For example, the head portion 40 may rotate along a first path S. The head portion 40 may be pressed in the direction of the polishing pad 20 (e.g., in a negative Z direction) to allow the wafer WF to be polished.

In one or more embodiments, the wafer WF may be a circular semiconductor wafer formed of silicon (Si). The wafer WF may also be formed of a material other than Si, such as gallium arsenide, sapphire, gallium nitride, ceramics, resin, or silicon carbide, and may not have any devices formed thereon.

The conditioner 50 may be a member for conditioning the surface of the polishing pad 20. Specifically, the conditioner 50 may polish the surface of the polishing pad 20 to maintain the surface roughness of the polishing pad 20 in an optimal state. The conditioner 50 may restore or maintain the surface roughness of the polishing pad 20 by polishing the polishing pad 20 either in a state of polishing the wafer WF with the head portion 40 or stopping the polishing of the wafer WF.

In one or more embodiments, the conditioner 50 may include abrasive particles, such as synthetic diamond particles, affixed onto a circular disk formed of a metal through a nickel (Ni) adhesive layer.

In one or more embodiments, the conditioner 50 may rotate in a predetermined direction. For example, the conditioner 50 may rotate in the same direction as the polishing platen 10 and the head portion 40, controlling the roughness of the polishing pad 20.

The slurry supply 60 may be a member for supplying a slurry to the polishing pad 20. The slurry supply 60, which may be located above the polishing pad 20, may supply the slurry to the polishing pad 20, allowing the slurry to be delivered to the wafer WF through the pores formed in the polishing pad 20. As a result, mechanical polishing of the wafer WF due to the rotation of the head portion 40, as well as chemical polishing of the wafer WF by the slurry may be performed simultaneously.

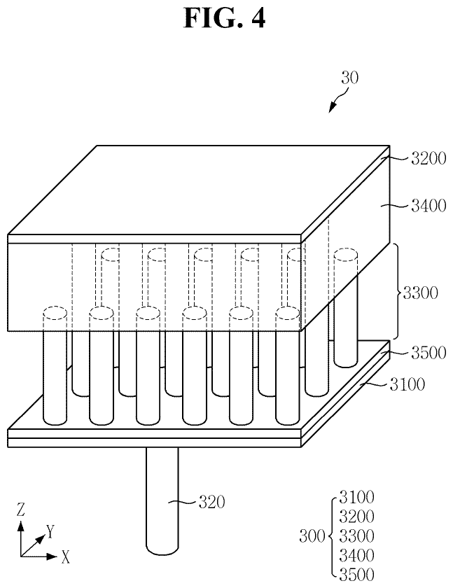

FIG. 4 is a perspective view illustrating an EPD according to one or more embodiments.

Referring to FIG. 4, an EPD 30 may include an acoustic sensor 300 and a signal cable 320. The acoustic sensor 300 may include a first electrode 3100, a second electrode 3200, a piezoelectric structure 3300, a connection film 3400, and a seed layer 3500.

The first and second electrodes 3100 and 3200 may be disposed to face each other while being spaced apart from each other by a predetermined distance. FIG. 4 illustrates that the first and second electrodes 3100 and 3200 as being in a rectangular plate shape, but the shape of the first and second electrodes 3100 and 3200 is not particularly limited. Alternatively, the first and second electrodes 3100 and 3200 may have a triangular or circular plate shape.

In one or more embodiments, the first electrode 3100 may include a conductive material. For example, the first electrode 3100 may include a conductive metal material such as aluminum (Al), copper (Cu), or an alloy thereof, or stainless use steel (SUS).

In one or more embodiments, the second electrode 3200 may include a conductive metal material such as Al, Cu, or an alloy thereof, or SUS, or a conductive polymer material, such as polyethersulfone (PES) coated with gold (Au) or platinum (Pt).

In one or more embodiments, the first electrode 3100 may be connected to the signal cable 320. The signal cable 320 may provide a pathway for electrons generated in the piezoelectric structure 3300 to flow to an external control device.

The piezoelectric structure 3300 may be located between the first and second electrodes 3100 and 3200. The piezoelectric structure 3300 may include a piezoelectric material. During a polishing process, electrons may be excited in the piezoelectric structure 3300 by sound waves or vibrations generated from the polishing surface of the wafer WF. The excited electrons may flow to the external control device through the first electrode 3100, the second electrode 3200, and the signal cable 320, forming an electrical signal. The external control device may determine the endpoint of the polishing process based on the electrical signal received through the signal cable 320.

In one or more embodiments, the piezoelectric structure 3300 may include a plurality of nanowires. The nanowires may be structures that grow the piezoelectric material into a rod shape with a fine diameter. The nanowires will be described later in further detail.

In this case, the acoustic sensor 300 may further include a seed layer 3500, which may be disposed between the piezoelectric structure 3300 and the first electrode 3100. The nanowires may be arranged in a two-dimensional (2D) array structure on the seed layer 3500. The seed layer 3500 may include the same piezoelectric material as the piezoelectric structure 3300.

In one or more embodiments, the piezoelectric structure 3300 may include an oxide semiconductor-series piezoelectric material. For example, the oxide semiconductor-series piezoelectric material may be ZnO, BaTiO₃, or lead zirconate titanate (PZT).

The connection film 3400 may be disposed between the piezoelectric structure 3300 and the second electrode 3200. The connection film 3400 may be disposed directly above the piezoelectric structure 3300 to contact the nanowires contained in the piezoelectric structure 3300. The connection film 3400 may electrically connect the piezoelectric structure 3300 and the second electrode 3200.

In one or more embodiments, the connection film 3400 may include a conductive polymer material, such as PES coated with Au or Pt.

Thus, an electrical signal generated in the piezoelectric structure 3300 due to sound waves may be transmitted to the external control device through the signal cable 320 along the first and second electrodes 3100 and 3200.

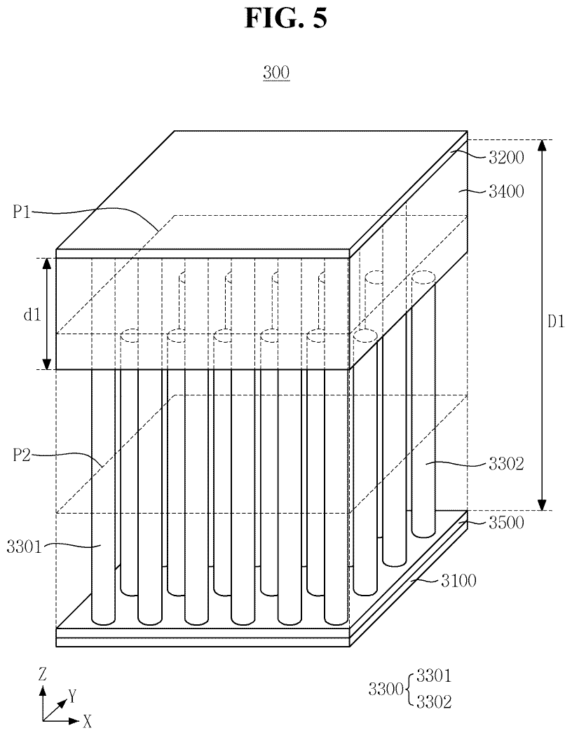

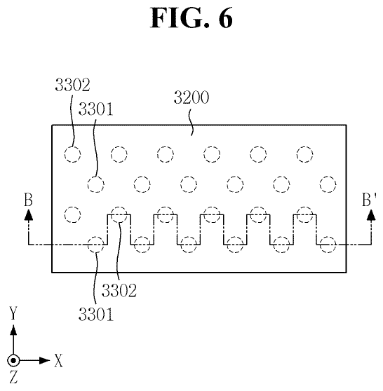

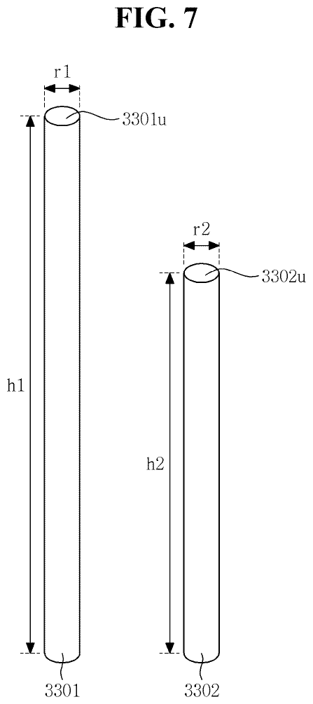

FIG. 5 is a perspective view illustrating an acoustic sensor according to one or more embodiments. FIG. 6 is a top view illustrating an acoustic sensor according to one or more embodiments. FIG. 7 is a diagram illustrating components depicted in FIG. 5 according to one or more embodiments.

Referring to FIGS. 5 through 7, an acoustic sensor 300 may include a first electrode 3100, a second electrode 3200, a piezoelectric structure 3300, a connection film 3400, and a seed layer 3500.

The first electrode 3100, the second electrode 3200, the connection film 3400, and the seed layer 3500 may be the same or similar to aspects as described above, and thus, repeated descriptions thereof may be omitted.

In one or more embodiments, the piezoelectric structure 3300 may include first nanowires 3301 and second nanowires 3302.

The first nanowires 3301 may have a first height h1. The second nanowires 3302 may have a second height h2, which is less than the first height h1. For example, the first and second heights h1 and h2 may be within the range of 10 μm to 1000 μm.

In one or more embodiments, the first nanowires 3301 may penetrate the connection film 3400 and directly contact the seed layer 3500 and the second electrode 3200.

For example, the distance between the second electrode 3200 and the seed layer 3500 may be a first sensor distance D1, and the height of the first nanowire 3301 may be the first height h1. The first height h1 of the first nanowires 3301 may be the same as the first sensor distance D1, but embodiments are not limited thereto.

In one or more embodiments, the second nanowires 3302 may be electrically connected to the second electrode 3200 by the connection film 3400. The connection film 3400 may contact top surfaces 3302u of the second nanowires 3302.

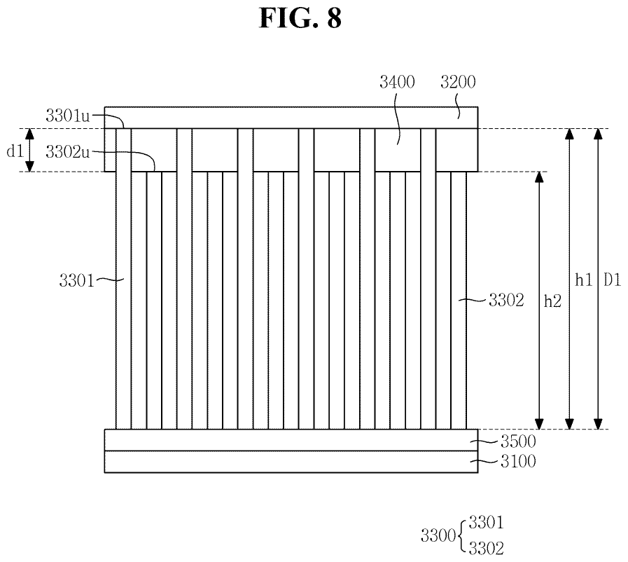

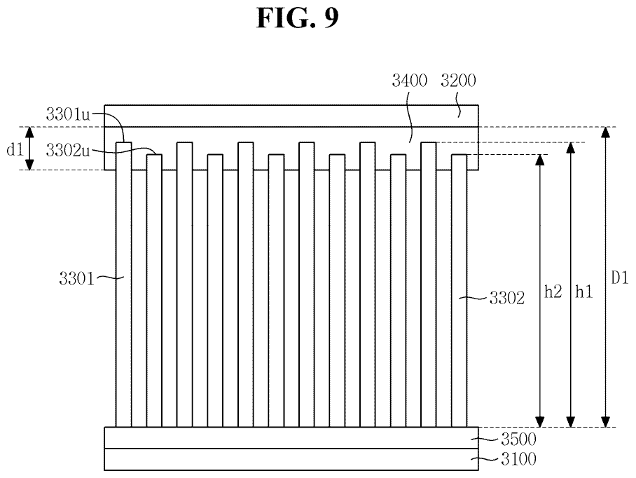

For example, the connection film 3400 may have a first thickness d1 and the second height h2. The sum of the first thickness d1 and the second height h2 may be equal to or greater than the first sensor distance D1, but embodiments are not limited thereto. This will be described in further detail with reference to FIGS. 8 and 9.

The first nanowires 3301 may have a first diameter r1. The second nanowires 3302 may have a second diameter r2. For example, the first and second diameters r1 and r2 may be within the range of 10 nm to 100 nm.

As the piezoelectric structure 3300 includes fine-size nanowires, electrical signals may be generated even by fine vibrations. Consequently, the sensitivity of the acoustic sensor 300 may be improved.

In one or more embodiments, the first nanowires 3301 and the second nanowires 3302 may include the same piezoelectric material or different piezoelectric materials. The piezoelectric material(s) of the first nanowires 3301 and second nanowires 3302 may be, for example, ZnO, BaTiO₃, or PZT.

For example, the first nanowires 3301 and the second nanowires 3302 may both include ZnO. Alternatively, the first nanowires 3301 and the second nanowires 3302 may both include BaTiO₃. However, embodiments are not limited to these examples.

The first nanowires 3301 may include ZnO, and the second nanowires 3302 may include BaTiO₃. However, embodiments are not limited to this example.

The first nanowires 3301 and the second nanowires 3302 are illustrated as being arranged along a first direction, respectively, alternating with one another in a second direction, but embodiments are not limited thereto. The positions and numbers of the first nanowires 3301 and the second nanowires 3302 included in the acoustic sensor 300 may vary.

FIG. 8 is cross-sectional view illustrating an example taken along line B-B′ of FIG. 6 according to one or more embodiments.

Referring to FIG. 8, the acoustic sensor 300 may include the first electrode 3100, the second electrode 3200, the piezoelectric structure 3300, the connection film 3400, and the seed layer 3500.

The first electrode 3100, the second electrode 3200, and the seed layer 3500 may be the same or similar to aspects as described above, and thus, repeated descriptions thereof may be omitted.

The piezoelectric structure 3300 may include first nanowires 3301 and second nanowires 3302.

In one or more embodiments, the first nanowires 3301 may penetrate the connection film 3400 and contact a surface of the second electrode 3200. That is, the top surfaces 3301u of the first nanowires 3301 may contact a surface of the second electrode 3200.

In one or more embodiments, the top surfaces 3302u of the second nanowires 3302 may contact a surface of the connection film 3400. Through the connection film 3400, which includes a conductive material, the second nanowires 3302 may be electrically connected to the second electrode 3200.

Electrons excited by the first nanowires 3301 and second nanowires 3302 may flow to the external control device through the first and second electrodes 3100 and 3200, forming an electrical signal.

FIG. 9 is cross-sectional view illustrating an example taken along line B-B′ of FIG. 6 according to one or more embodiments.

Referring to FIG. 9, an acoustic sensor 300 may include a first electrode 3100, a second electrode 3200, a piezoelectric structure 3300, a connection film 3400, and a seed layer 3500.

The first electrode 3100, the second electrode 3200, and the seed layer 3500 may be the same or similar to aspects as described above, and thus, repeated descriptions thereof may be omitted.

The piezoelectric structure 3300 may include first nanowires 3301 and second nanowires 3302.

In one or more embodiments, top surfaces 3301u of the first nanowires 3301 may contact the connection film 3400. Similarly, top surfaces 3302u of the second nanowires 3302 may also contact the connection film 3400. Through the connection film 3400, which includes a conductive material, the first nanowires 3301 and the second nanowires 3302 may both be electrically connected to the second electrode 3200.

Electrons excited in both the first nanowires 3301 and the second nanowires 3302 may flow to an external control device through the first and second electrodes 3100 and 3200, generating an electrical signal.

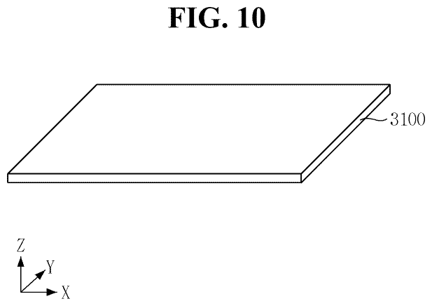

FIGS. 10 through 14 are perspective views illustrating a method of manufacturing an acoustic sensor according to one or more embodiments.

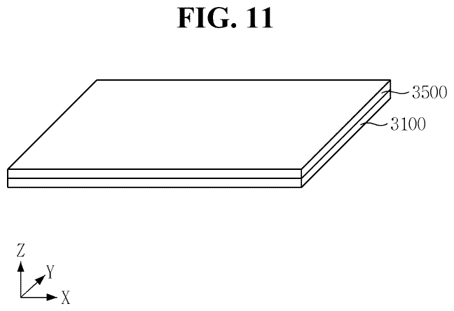

Referring to FIGS. 10 and 11, a seed layer 3500 may be provided on a first electrode 3100. The seed layer 3500 may be for forming a piezoelectric structure 3300 (which may include a piezoelectric material) between the first and second electrodes 3100 and 3200.

The seed layer 3500 may include a piezoelectric material. The seed layer 3500 may include the same piezoelectric material as the piezoelectric structure 3300. The piezoelectric material of the seed layer 3500 may be, for example, at least one of ZnO, BaTiO₃, and PZT.

The seed layer 3500 may be formed by various methods. The seed layer 3500 may be formed on the first electrode 3100 by chemical vapor deposition (CVD) or physical vapor deposition (PVD) such as sputtering. For example, the seed layer 3500 may also be formed by sol-gel spin coating.

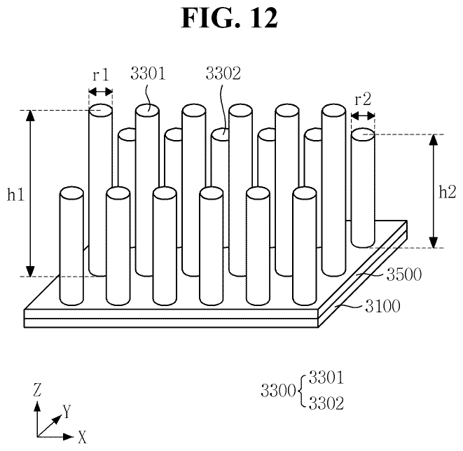

Referring to FIG. 12, the piezoelectric structure 3300 may be formed on the seed layer 3500. The piezoelectric structure 3300 may include at least one of ZnO, BaTiO₃, and PZT.

In one or more embodiments, the piezoelectric structure 3300 may include two types of nanowires with different heights, such as the first nanowires 3301 and second nanowires 3302, but the embodiments are not limited thereto. Alternatively, the piezoelectric structure 3300 may include more than three types of nanowires with different heights. The piezoelectric structure 3300 may be formed on the seed layer 3500 by various methods. For example, the piezoelectric structure 3300 may be grown on the seed layer 3500 by a hydrothermal method.

The piezoelectric structure 3300 may grow on the seed layer 3500 perpendicularly to the surface of the seed layer 3500 (for example, in a third direction Z). The piezoelectric structure 3300 may be arranged in a direction parallel to the surface of the seed layer 3500 (for example, in a first direction X or a second direction Y).

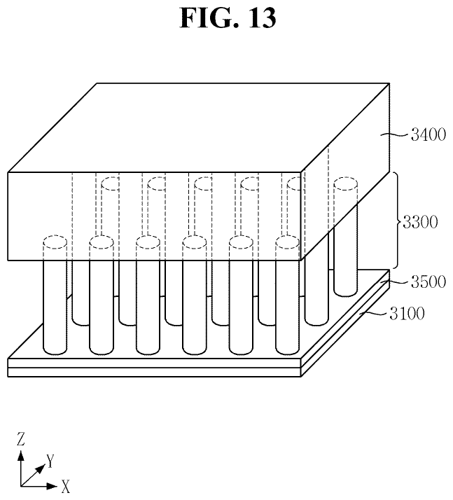

Referring to FIG. 13, a connection film 3400 may be formed on the piezoelectric structure 3300. The connection film 3400 may be disposed directly above the piezoelectric structure 3300 to contact the top surfaces of the nanowires included in the piezoelectric structure 3300. The connection film 3400 may electrically connect the piezoelectric structure 3300 and the second electrode 3200.

In one or more embodiments, the connection film 3400 may be formed on the piezoelectric structure 3300 by CVD or PVD.

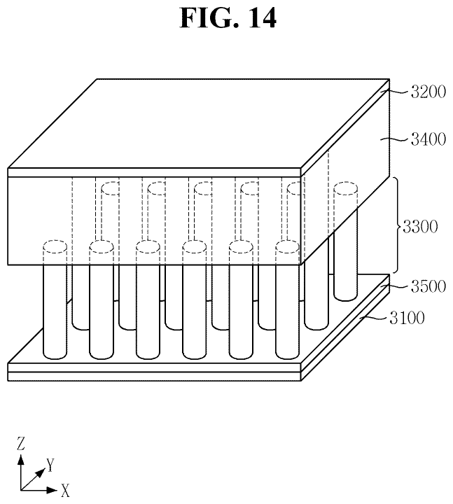

Referring to FIG. 14, a second electrode 3200 may be formed on the connection film 3400.

In one or more embodiments, the second electrode 3200 may include the same material as the first electrode 3100. For example, the second electrode 3200 may include a conductive metal material such as Al, Cu, or an alloy thereof, or SUS, or a conductive polymer material, such as PES coated with Au or Pt.

In one or more embodiments, the second electrode 3200 may be formed on the connection film 3400 by CVD or PVD.

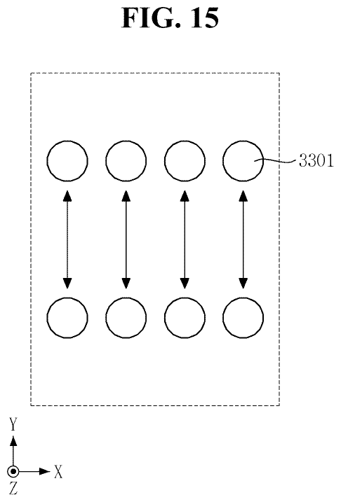

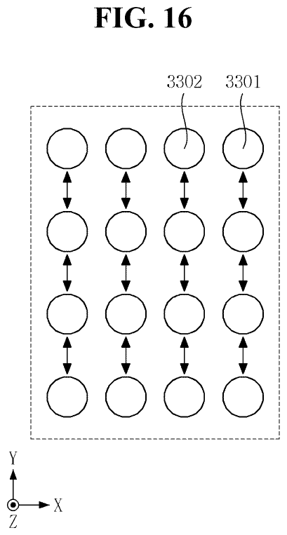

FIG. 15 is a cross-sectional view illustrating portion P1 of FIG. 5 according to one or more embodiments. FIG. 16 is a cross-sectional view illustrating portion P2 of FIG. 5 according to one or more embodiments.

Referring to FIGS. 5, 15, and 16, the piezoelectric structure 3300 may include first nanowires 3301 and second nanowires 3302 with a different height from the first nanowires 3301, and as a result, the porosity within the piezoelectric structure 3300 may be increased.

For example, the first nanowires 3301 and the second nanowires 3302 may be both disposed on a lower plane P2, resulting in a low porosity. On the contrary, only the first nanowires 3301 may be positioned on an upper plane P1, resulting in a higher porosity than on the lower plane P2.

Thus, as the first nanowires 3301 and the second nanowires 3302 with a different height from the first nanowires 3301 are provided, the internal porosity of the acoustic sensor 300 may be adjusted. Consequently, the amount of charge generated by sound waves reaching a unit area may be increased, thereby enhancing signal sensitivity.

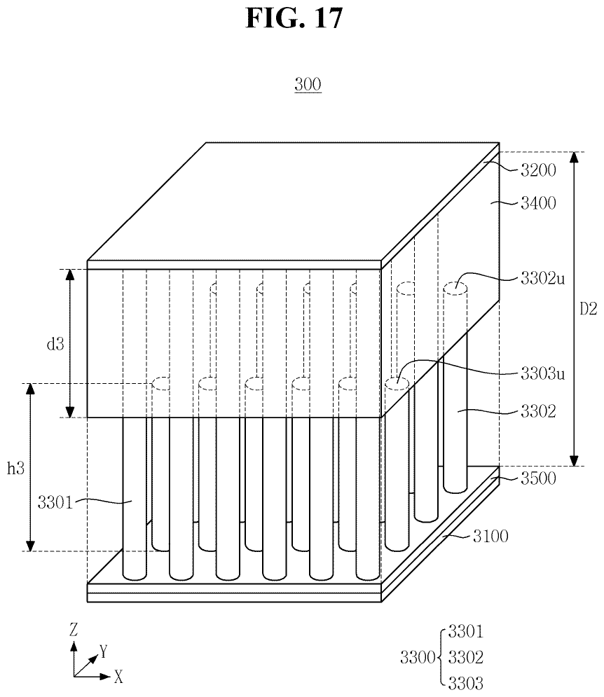

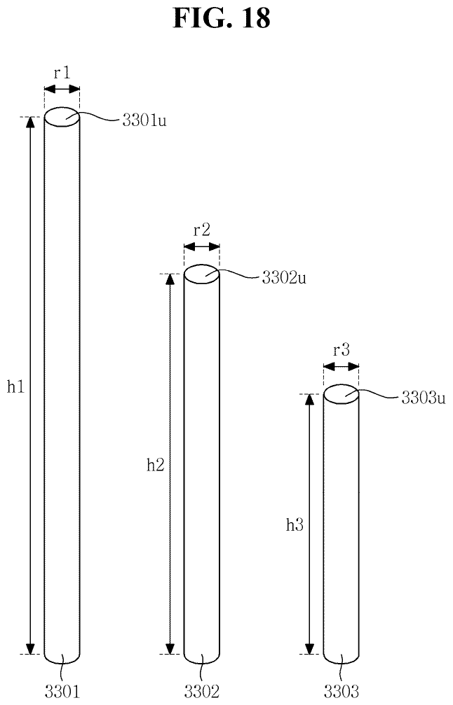

FIG. 17 is a perspective view illustrating an acoustic sensor according to one or more embodiments. FIG. 18 is a perspective view illustrating components depicted in FIG. 17 according to one or more embodiments.

Referring to FIGS. 17 and 18, an acoustic sensor 300 may include a first electrode 3100, a second electrode 3200, a piezoelectric structure 3300, a connection film 3400, and a seed layer 3500.

The first electrode 3100, the second electrode 3200, the connection film 3400, and the seed layer 3500 may be the same or similar to aspects as described above, and thus, repeated descriptions thereof may be omitted.

In one or more embodiments, the piezoelectric structure 3300 may include first nanowires 3301, second nanowires 3302, and third nanowires 3303.

The first nanowires 3301 may have a first height h1. The second nanowires 3302 may have a second height h2, which is less than the first height h1. The third nanowires 3303 may have a third height h3, which is less than the second height h2. For example, the first, second, and third heights h1, h2, and h3 may range from 10 μm to 1000 μm.

In one or more embodiments, the first nanowires 3301 may penetrate the connection film 3400 and directly contact the seed layer 3500 and the second electrode 3200.

For example, the distance between the second electrode 3200 and the seed layer 3500 may be a second sensor distance D2, and the first nanowire 3301 may have a first height h1. The first height h1 of the first nanowire 3301 may be the same as the second sensor distance D2, but embodiments are not limited thereto.

In one or more embodiments, the second nanowires 3302 and the third nanowires 3303 may be electrically connected to the second electrode 3200 through the connection film 3400. The connection film 3400 may contact top surfaces 3302u of the second nanowires 3302 and top surfaces 3303u of the third nanowires 3303.

For example, the connection film 3400 may have a second thickness d2, and the second nanowires 3302 may have a second height h2. The sum of the first thickness d1 and the second height h2 may be equal to or greater than the second sensor distance D2, but embodiments are not limited thereto.

For example, the connection film 3400 may have the second thickness d2, and the third nanowires 3303 may have a third height h3. The sum of the second thickness d2 and the third height h3 may be equal to or greater than the second sensor distance D2, but embodiments are not limited thereto.

The first nanowires 3301 may have a first diameter r1. The second nanowires 3302 may have a second diameter r2. The third nanowires 3303 may have a third diameter r3. For example, the first, second, and third diameters r1, r2, and r3 may range from 10 nm to 100 nm.

As nanowires of fine sizes are included in the piezoelectric structure 3300, electrical signals may be generated even by fine vibrations. As a result, the sensitivity of the acoustic sensor 300 may be enhanced.

In one or more embodiments, the first nanowires 3301, the second nanowires 3302, and the third nanowires 3303 may include the same piezoelectric material or different piezoelectric materials. The piezoelectric material(s) of the first nanowires 3301, second nanowires 3302, and third nanowires 3303 may be, for example, ZnO, BaTiO₃, or PZT.

For example, the first nanowires 3301, the second nanowires 3302, and the third nanowires 3303 may all include ZnO. Alternatively, the first nanowires 3301, the second nanowires 3302, and the third nanowires 3303 may all include BaTiO₃.

The first nanowire 3301 may include ZnO, the second nanowire 3302 may include BaTiO₃, and the third nanowire 3303 may include PZT. However, embodiments are not limited to these examples.

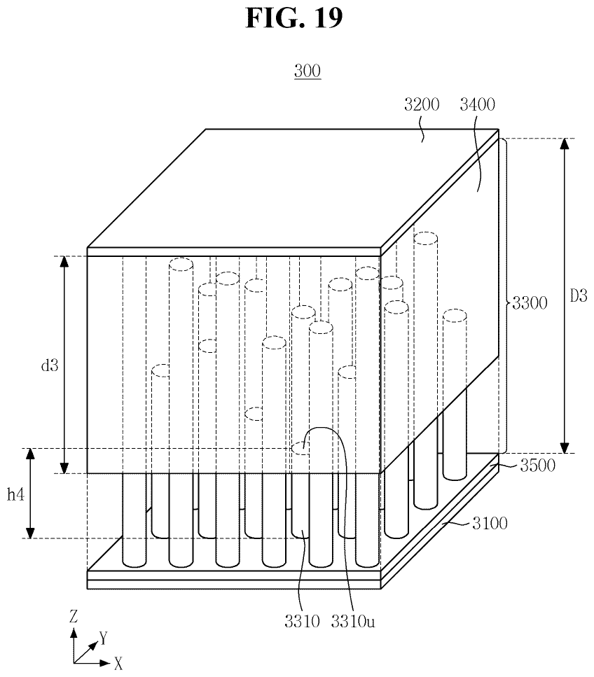

FIG. 19 is a perspective view illustrating an acoustic sensor according to one or more embodiments.

Referring to FIG. 19, an acoustic sensor 300 may include a first electrode 3100, a second electrode 3200, a piezoelectric structure 3300, a connection film 3400, and a seed layer 3500.

The first electrode 3100, the second electrode 3200, the connection film 3400, and the seed layer 3500 may be the same or similar to aspects as described above, and thus, repeated descriptions thereof may be omitted.

In one or more embodiments, the piezoelectric structure 3300 may include a plurality of nanowires with irregular heights, including fourth nanowires 3310. The fourth nanowires 3310 may have a smallest height among the plurality of nanowires.

In one or more embodiments, the fourth nanowires 3310 may be electrically connected to the second electrode 3200 through the connection film 3400. The connection film 3400 may contact top surfaces 3310u of the fourth nanowires 3310. The distance between the second electrode 3200 and the seed layer 3500 may be a third sensor distance D3.

For example, the connection film 3400 may have a third thickness d2, and the fourth nanowires 3310 may have a fourth height h4. The sum of the third thickness d2 and the fourth height h4 may be equal to or greater than the third sensor distance D3, but embodiments are not limited thereto.

In one or more embodiments, the plurality of nanowires may include the same piezoelectric material or different piezoelectric materials from the fourth nanowires 3310. The piezoelectric material(s) of the plurality of nanowires, including the fourth nanowires 3310, may be, for example, ZnO, BaTiO₃, or PZT.

For example, the plurality of nanowires, including the fourth nanowires 3310, may all include ZnO. Alternatively, the plurality of nanowires, including the fourth nanowires 3310, may all include BaTiO₃. However, embodiments are not limited thereto.

The plurality of nanowires, including the fourth nanowires 3310, may include one of ZnO, BaTiO₃, and PZT, but embodiments are not limited thereto.

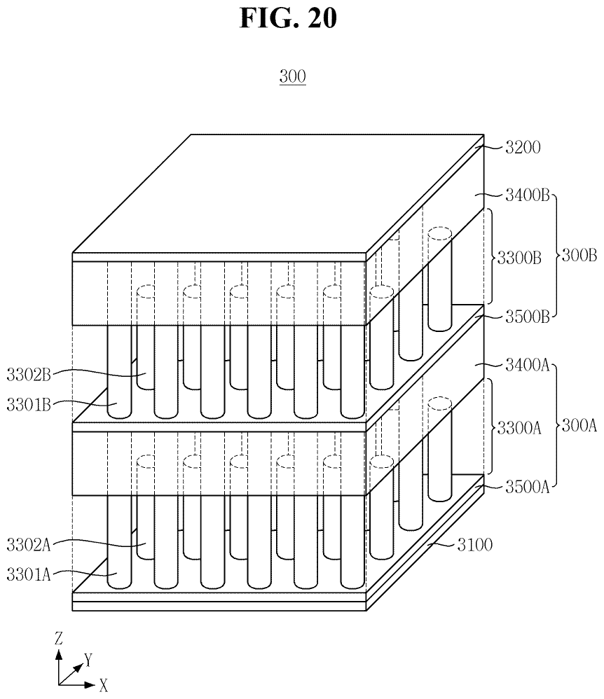

FIG. 20 is a perspective view illustrating an acoustic sensor according to one or more embodiments.

Referring to FIG. 20, the acoustic sensor 300 may include a first sub-acoustic sensor 300A and a second sub-acoustic sensor 300B. The acoustic sensor 300 may further include a first electrode 3100 and a second electrode 3200.

A first seed layer 3500A, a first piezoelectric structure 3300A, a first connection film 3400A, a second seed layer 3500B, a second piezoelectric structure 3300B, and a second connection film 3400B may be sequentially arranged between the first and second electrodes 3100 and 3200.

The first and second sub-acoustic sensors 300A and 300B may be electrically connected to each other through the first connection film 3400A and the second seed layer 3500B.

Generally, the longer the nanowires containing a piezoelectric material, the stronger the electrical signals that may be generated from the piezoelectric material. However, it may not always be easy to grow nanowires containing a piezoelectric material to a target length on the first and second seed layers 3500A and 3500B. In such cases, as illustrated in FIG. 20, a single acoustic sensor 300 may be formed by stacking two or more sub-acoustic sensors, such as the first and second sub-acoustic sensors 300A and 300B. Accordingly, the same effect of growing nanowires to the target length may be achieved.

The acoustic sensor 300 may be substantially the same as its counterpart of FIG. 5 except that it has a structure where two or more sub-acoustic sensors are stacked vertically.

The first piezoelectric structure 3300 may include first sub-nanowires 3301A and second sub-nanowires 3302A.

The height of the first sub-nanowires 3301A may be greater than the height of the second sub-nanowires 3302A.

In one or more embodiments, the first sub-nanowires 3301A may penetrate the first sub-connection film 3400A and directly contact the second sub-seed layer 3500B. The second sub-nanowires 3302A may be electrically connected to a second piezoelectric structure 3300B by the first sub-connection film 3400A. The first sub-connection film 3400A may contact the top surfaces of the second sub-nanowires 3302A.

In one or more embodiments, the first sub-nanowires 3301A and the second sub-nanowires 3302A may include the same piezoelectric material or different piezoelectric materials. The piezoelectric material(s) of the first sub-nanowires 3301A and second sub-nanowires 3302A may be, for example, ZnO, BaTiO₃, or PZT.

For example, the first sub-nanowires 3301A and the second sub-nanowires 3302A may both include ZnO. Alternatively, the first sub-nanowires 3301A may include ZnO, and the second sub-nanowires 3302A may include BaTiO₃. However, the embodiments are not limited to these examples.

The second piezoelectric structure 3300B may include third sub-nanowires 3301B and fourth sub-nanowires 3302B.

The height of the third sub-nanowires 3301B may be greater than the height of the fourth sub-nanowires 3302B.

In one or more embodiments, the third sub-nanowires 3301B may penetrate the second sub-connection film and may directly contact the second electrode 3200. The fourth sub-nanowires 3302B may be electrically connected to the second electrode 3200 through the second sub-connection film 3400B. The second sub-connection film 3400B may contact the top surfaces of the fourth sub-nanowires 3302B.

In one or more embodiments, the third sub-nanowires 3301B and the fourth sub-nanowires 3302B may include the same piezoelectric material or different piezoelectric materials. The piezoelectric material(s) of the third sub-nanowires 3301B and fourth sub-nanowires 3302B may be, for example, ZnO, BaTiO₃, or PZT.

For example, the third sub-nanowires 3301B and the fourth sub-nanowires 3302B may both include ZnO. Alternatively, the third sub-nanowires 3301B may include ZnO, and the fourth sub-nanowires 3302B may include BaTiO₃. However, embodiments are not limited to these examples.

Each of the first and second piezoelectric structures 3300A and 3300B is illustrated as including two types of sub-nanowires with different heights, but embodiments are not limited thereto. Alternatively, each of the first and second piezoelectric structures 3300A and 3300B may include more than three types of sub-nanowires with different heights.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An acoustic sensor comprising:
a first electrode;
a second electrode spaced apart from the first electrode in a first direction; and
a first piezoelectric structure between the first electrode and the second electrode,
wherein the first piezoelectric structure comprises:
first nanowires extending in the first direction and having a first height; and
second nanowires extending in the first direction and having a second height that is less than the first height.

2. The acoustic sensor of claim 1, further comprising:
a connection film between the first electrode and the second electrode,
wherein the connection film contacts top surfaces of the second nanowires, and
wherein the first nanowires penetrate the connection film and contact the second electrode.

3. The acoustic sensor of claim 1, further comprising:
a connection film between the first electrode and the second electrode,
wherein the connection film contacts top surfaces of the first nanowires and top surfaces of the second nanowires.

4. The acoustic sensor of claim 1, wherein the first nanowires comprise a first piezoelectric material, and
wherein the second nanowires comprise a second piezoelectric material that is different from the first piezoelectric material.

5. The acoustic sensor of claim 4, wherein the first piezoelectric material and the second piezoelectric material comprise one of BaTiO₃, ZnO, or lead zirconate titanate (PZT).

6. The acoustic sensor of claim 4, further comprising:
a seed layer on the first electrode,
wherein the first nanowires and the second nanowires are on the seed layer, and
wherein the seed layer comprises the first piezoelectric material or the second piezoelectric material.

7. The acoustic sensor of claim 1, wherein the first piezoelectric structure further comprises third nanowires having a third height that is less than the first height and that is greater than the second height.

8. The acoustic sensor of claim 1, further comprising:
a first connection film and a second piezoelectric structure between the first electrode and the second electrode,
wherein the first piezoelectric structure is between the first electrode and the first connection film,
wherein the first connection film contacts top surfaces of the second nanowires,
wherein the first nanowires penetrate the first connection film,
wherein the second piezoelectric structure is between the first connection film and the second electrode, and
wherein the second piezoelectric structure comprises third nanowires extending in the first direction, having a third height, and connected to the second electrode.

9. The acoustic sensor of claim 8, wherein the second piezoelectric structure further comprises fourth nanowires extending in the first direction and having a fourth height that is different from the third height.

10. The acoustic sensor of claim 9, further comprising:
a second connection film between the second piezoelectric structure and the second electrode,
wherein the second connection film contacts top surfaces of the fourth nanowires, and
wherein the third nanowires penetrate the second connection film and contact the second electrode.

11. The acoustic sensor of claim 8, further comprising:
a first seed layer between the first electrode and the first piezoelectric structure; and
a second seed layer between the first connection film and the second piezoelectric structure.

12. A chemical mechanical polishing (CMP) apparatus comprising:
a polishing platen;
a polishing pad on the polishing platen;
a polishing head on the polishing pad and comprising a wafer receptacle configured to accommodate a wafer; and
an acoustic sensor in the polishing pad,
wherein the acoustic sensor comprises:
a first electrode;
a second electrode spaced apart from the first electrode in a first direction; and
a first piezoelectric structure between the first electrode and the second electrode, and
wherein the first piezoelectric structure comprises:
first nanowires extending in the first direction and having a first height; and
second nanowires extending in the first direction and having a second height that is less than the first height.

13. The acoustic sensor of claim 12, further comprising:
a connection film between the first electrode and the second electrode,
wherein the connection film contacts top surfaces of the second nanowires, and
wherein the first nanowires penetrate the connection film and contact the second electrode.

14. The acoustic sensor of claim 12, further comprising:
a connection film between the first electrode and the second electrode,
wherein the connection film contacts top surfaces of the first nanowires and top surfaces of the second nanowires.

15. The acoustic sensor of claim 12, wherein the first nanowires comprise a first piezoelectric material, and
wherein the second nanowires comprise a second piezoelectric material that is different from the first piezoelectric material.

16. The acoustic sensor of claim 15, wherein the first piezoelectric material and the second piezoelectric material comprise one of BaTiO₃, ZnO, or lead zirconate titanate (PZT).

17. The acoustic sensor of claim 15, further comprising:
a seed layer on the first electrode,
wherein the first nanowires and the second nanowires are on the seed layer, and
wherein the seed layer comprises the first piezoelectric material or the second piezoelectric material.

18. The acoustic sensor of claim 12, wherein the first piezoelectric structure further comprises third nanowires having a third height that is less than the first height and that is greater than the second height.

19. A method of manufacturing an acoustic sensor, comprising:
providing a seed layer on a first electrode;
forming first nanowires on the seed layer, the first nanowires extending in a first direction and having a first height;
forming second nanowires on the seed layer, the second nanowires extending in the first direction and having a second height that is less than the first height;
forming a connection film contacting top surfaces of the second nanowires; and
providing a second electrode on the connection film.

20. The method of claim 19, wherein the first nanowires comprise a first piezoelectric material, and
wherein the second nanowires comprise a second piezoelectric material that is different from the first piezoelectric material.
